(19) United States
(12) Patent Application Publication
(10) Pub. No.: US 2006/0163729 A1
(43) Pub. Date: Jul. 27, 2006

(54) Structure and manufacturing method of a chip scale package

(76) Inventors: Mou-Shiung Lin, Hsinchu (TW); Ming-Ta Lei, Hsinchu (TW); Chuen-Jye Lin, Taichung (TW)

Correspondence Address: Saile Ackerman LLC, 28 Davis Avenue, Poughkeepsie, NY, 12603, US

(21) Appl. No.: 11/389,717

(22) Filed: Mar. 27, 2006

Related U.S. Application Data
(63) Continuation of application No. 09/837,007, filed on Apr. 18, 2001.

(51) Int. Cl. H01L 23/48; H01L 23/52; H01L 29/40

(52) U.S. Cl. 257/738

(57) ABSTRACT

A new method and package is provided for the mounting of semiconductor devices that have been provided with small-pitch Input/Output interconnect bumps. Fine pitch solder bumps, consisting of pillar metal and a solder bump, are applied directly to the I/O pads of the semiconductor device, the device is then flip-chip bonded to a substrate. Dummy bumps may be provided for cases where the I/O pads of the device are arranged such that additional mechanical support for the device is required.

This is a Continuation application of U.S. patent application Ser. No. 09/837,007, filed on Apr. 18, 2001, which is herein incorporated by reference in its entirety, and assigned to a common assignee.

### RELATED PATENT APPLICATION

This application is related to Ser. No. 09/798,654 (MEG01-003) filed on Mar. 5, 2001, now U.S. Pat. No. 6,818,545 issued on Nov. 16, 2004 and to Ser. No. 10/935,451 (MEG01-003 B) filed on Sep. 7, 2004, both assigned to a common assignee.

### BACKGROUND OF THE INVENTION

(1) Field of the Invention

The invention relates to the fabrication of integrated circuit devices, and more particularly, to a method and package for packaging semiconductor devices.

(2) Description of the Prior Art

Semiconductor device performance improvements are largely achieved by reducing device dimensions, a development that has at the same time resulted in considerable increases in device density and device complexity. These developments have resulted in placing increasing demands on the methods and techniques that are used to access the devices, also referred to as Input/Output (I/O) capabilities of the device. This has led to new methods of packaging semiconductor devices whereby structures such as Ball Grid Array (BGA) devices and Column Grid Array (CGA) devices have been developed. A Ball Grid Array (BGA) is an array of solder balls placed on a chip carrier. The balls contact a printed circuit board in an array configuration where, after reheat, the balls connect the chip to the printed circuit board. BGA's are known with 40, 50 and 60 mil spacings. Due to the increased device miniaturization, the impact that device interconnects have on device performance and device cost has also become a larger factor in package development. Device interconnects, due to their increase in length in order to package complex devices and connect these devices to surrounding circuitry, tend to have an increasingly negative impact on the package performance. For longer and more robust metal interconnects, the parasitic capacitance and resistance of the metal interconnection increase, which degrades the chip performance significantly. Of particular concern in this respect is the voltage drop along power and ground buses and the RC delay that is introduced in the critical signal paths.

One of the more recent developments that is aimed at increasing the Input-Output (I/O) capabilities of semiconductor device packages is the development of Flip Chip Packages. Flip-chip technology fabricates bumps (typically Pb/Sn solders) on aluminum pads on a semiconductor device. The bumps are interconnected directly to the package media, which are usually ceramic or plastic based. The flip-chip is bonded face down to the package medium through the shortest paths.

In general, Chip-On-Board (COB) techniques are used to attach semiconductor die to a printed circuit board, these techniques include the technical disciplines of flip chip attachment, wirebonding, and tape automated bonding (TAB). Flip chip attachment consists of attaching a flip chip to a printed circuit board or to another substrate. A flip chip is a semiconductor chip that has a pattern or arrays of terminals that are spaced around an active surface area of the flip chip, allowing for face down mounting of the flip chip to a substrate.

Generally, the flip chip active surface has one of the following electrical connectors: BGA (wherein an array of minute solder balls is created on the surface of the flip chip that attaches to the substrate); Slightly Larger than Integrated Circuit Carrier (SLICC) (which is similar to the BGA but has a smaller solder ball pitch and diameter than the BGA); a Pin Grid Array (PGA) (wherein an array of small pins extends substantially perpendicularly from the attachment surface of a flip chip, such that the pins conform to a specific arrangement on a printed circuit board or other substrate for attachment thereto. With the BGA or SLICC, the solder or other conductive ball arrangement on the flip chip must be a mirror image of the connecting bond pads on the printed circuit board so that precise connection can be made.

The invention addresses concerns of creating a BGA type package whereby the pitch of the solder ball or solder bump of the device interconnect is in the range of 200 μm or less. The conventional, state-of-the-art solder process runs into limitations for such a fine interconnect pad pitch, the invention provides a method and a package for attaching devices having very small ball pitch to an interconnect medium such as a Printed Circuit Board.

### SUMMARY OF THE INVENTION

A principle objective of the invention is to provide a method for applying fine pitch solder bumps directly to the I/O pads of a semiconductor device, without a redistribution interface, and bonding the semiconductor device directly to a Ball Grid Array substrate using the flip-chip bonding approach.

Another objective of the invention is to provide a method for shortening the interconnection between a semiconductor device and the substrate on which the device is mounted, thus improving the electrical performance of the device.

Yet another objective of the invention is to eliminate conventional methods of re-distribution of device I/O interconnect, thereby making packaging of the device more cost-effective and eliminating performance degradation.

A still further objective of the invention is to improve chip accessibility during testing of the device, thus eliminating the need for special test fixtures.

A still further objective of the invention is to improve performance and device reliability of BGA packages that are used for the mounting of semiconductor devices having small-pitch I/O interconnect bumps.

A still further objective of the invention is to perform Chip Scale Packaging (CSP) without re-distribution, including for various pad designs such as peripheral or central pad designs.

A still further objective of the invention is to provide a method of mounting small-pitch semiconductor devices in such a manner that flux removal and the dispensing of device encapsulants is improved.

In accordance with the objectives of the invention a new method and package is provided for the mounting of semiconductor devices that have been provided with small-pitch Input/Output interconnect bumps. Fine pitch solder bumps, consisting of pillar metal and a solder bump, are applied directly to the I/O pads of the semiconductor device, the device is then flip-chip bonded to a substrate. Dummy bumps may be provided for cases where the I/O pads of the device are arranged such that additional mechanical support for the device is required.

### BRIEF DESCRIPTION OF THE DRAWINGS

FIG. 1 shows a cross section of a prior art Ball Grid Array package, the semiconductor device is enclosed in a molding.

FIG. 2 shows a cross section of a prior art Ball Grid Array package, underfill is provided for the semiconductor device.

FIG. 3 shows a cross section of a first solder bump that has been created in accordance with the above referenced related application, this drawing has been extracted from the related application for reference purposes.

FIG. 4 shows a cross section of a second solder bump that has been created in accordance with the above referenced related application, this drawing has been extracted from the related application for reference purposes.

FIG. 5 shows a cross section of the BGA package of the invention, the semiconductor device is encapsulated in a molding compound.

FIG. 6 shows a cross section of the BGA package of the invention, underfill is provided to the semiconductor device.

FIG. 7 shows a top view of an array type I/O pad configuration of a semiconductor device.

FIG. 8 shows a top view of a peripheral type I/O pad configuration of a semiconductor device.

FIG. 9 shows a top view of a center type I/O pad configuration of a semiconductor device.

FIG. 10 shows a top view of a center type I/O pad configuration of a semiconductor device, dummy solder bumps have been provided in support of the semiconductor device.

FIG. 11 shows a top view of the substrate with exposed I/O contact pads, this exposure is accomplished by not depositing the solder mask in close proximity to the contact pads of the semiconductor device.

FIG. 12 shows a cross section of the substrate of FIG. 11.

FIG. 13 shows a top view of a prior art substrate with exposed I/O contact pads, the solder mask is in close proximity to the contact pads of the semiconductor device.

FIG. 14 shows a cross section of the substrate of FIG. 13.

FIGS. 15a through 15f show examples of applications of the invention.

FIGS. 16a and 16b demonstrate how the invention leads to the ability to reduce the pitch between I/O pads.

### DESCRIPTION OF THE PREFERRED EMBODIMENTS

The above stated objective of improving chip accessibility during testing of the device, thus eliminating the need for special test fixtures, can further be highlighted as follows. The disclosed method of the invention, using Chip Scale Packaging (CSP), can control the cost of testing CSP devices by keeping the same body size of the chip and by using the same size substrate. For conventional CSP packages, the chip may have different body sizes, which imposes the requirement of different size test fixtures. With the continued reduction of the size of semiconductor devices, additional and varying device sizes are expected to be used. This would result in ever increasing costs for back-end testing of the devices in a production environment. The invention provides a method where these additional back-end testing costs can be avoided.

Referring now to FIG. 1, there is shown a cross section of a typical flip chip package with the semiconductor device being encapsulated in a molding compound. The Integrated Circuit (IC) device 10 enters the process as a separate unit with the contact points (balls 16) attached to the bottom of the chip 10. The IC 10 is placed on the surface of a BGA substrate 12, an (optional) interconnect substrate 14 has been provided for additional routing of the electrical network to which device 10 is attached. The balls 18 that are connected to the lower surface of the substrate 12 make contact with surrounding circuitry (not shown). The paths of electrical interconnect of device 10 as shown in cross section in FIG. 1 is as follows: contact pumps (points of I/O interconnect, not shown in FIG. 1) are provided on the surface of device that faces substrate 12, contact balls 16 are connected to these contact bumps. Contact balls 16 interface with points of contact (contact pads) provided in the surface of the (optional) interconnect network 14 or, for applications where the interconnect interface 14 is not provided, with points of contact (contact pads) provided in the surface of the Ball Grid Array (BGA) substrate 12. BGA substrate 12 may further have been provided with one or more layers of interconnect metal, all of the interfaces (the interconnect substrate 12 and the optional redistribution lines provided in BGA substrate 12) result in interconnecting balls 16 with balls 18. Balls 18 are the contact points that connect the package that is shown in cross section in FIG. 1 to surrounding circuitry.

Whereas the cross section that is shown in FIG. 1 shows contact balls 16 for the establishment of contacts between device 10 and the underlying substrate 12, some prior art applications still used wire bond connections (not shown in FIG. 1), this in order to achieve optimum electrical performance of the device package.

Further shown in the cross section of FIG. 1 is layer 19, which may be provided over the surface of semiconductor device 10 facing the substrate 12. This re-distribution layer provides interconnect lines over the surface of device 10 and is required in prior art applications if solder bumps are required on current pad layout for wire bonding purposes. The main purpose of the redistribution layer is to enlarge the pitch of solder bump interconnects if the bond pads are originally designed for wire bonding applications. It will be clear from later explanations that the invention removes the need for the redistribution layer.

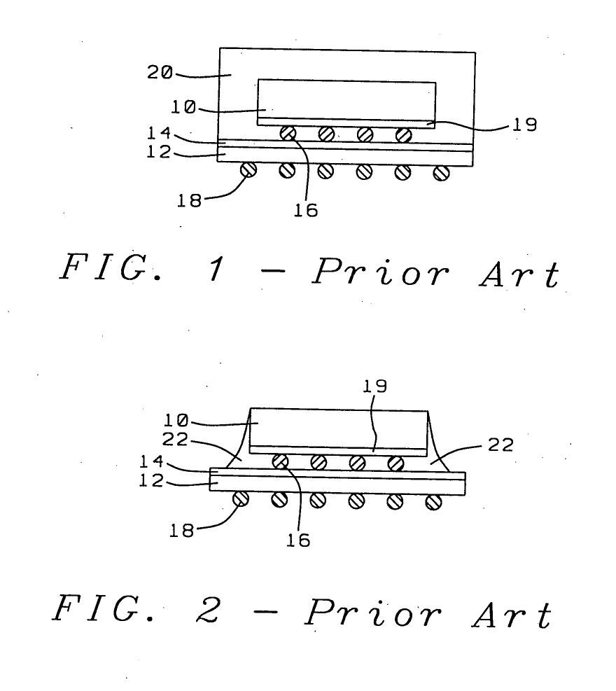

FIG. 2 shows a cross section of a conventional BGA package whereby the semiconductor device 10 is provided with underfill 22, no molding compound (20, FIG. 1) has been provided in the package that is shown in cross section in FIG. 2. All the other statements that relate to the electrical interconnection of the device 10 of FIG. 2 are identical to the statements that have been made in the description provided for the package of FIG. 1. It should be noted in FIG. 2 that the sides of the underfill 22 are sloping such that the physical contact between the underfill 22 and the substrate 12 is extended beyond the dimensions of the bottom surface of the chip 10. This is a normal phenomenon with liquid underfill, which enhances the mechanical strength between the substrate 12 and the IC chip 10.

Referring now to FIG. 3, there is shown a cross section of a first solder bump that has been created in accordance with the above referenced related application, this drawing has been extracted from the related application for reference purposes. The elements that are shown in FIG. 3 that form part of the solder bump of the related application are the following:
10, a semiconductor surface such as the surface of a substrate
30, a layer of dielectric that has been deposited over the semiconductor surface 10
32, contact pads that have been created on the surface of the layer 30 of dielectric
34, a patterned layer of passivation that has been deposited over the surface of the layer 30 of dielectric; openings have been created in the layer 34 of passivation, partially exposing the surface of contact pads 32
36, an isotropically etched layer of barrier metal; because this layer of barrier metal has been isotropically etched, the barrier metal has been completely removed from the surface of the layer 34 of passivation except where the barrier metal is covered by the overlying pillar metal (38) of the solder bump
38, the pillar metal of the solder bump
40, a layer of under bump metal created overlying the pillar metal 38 of the solder bump
42, the solder metal.

The cross section that is shown in FIG. 4 is similar to the cross section of FIG. 3 with the exception of layer 35, which is an anisotropically etched layer of barrier metal (etched after the solder bump 42 has been created) which, due to the nature of the anisotropic etch, protrudes from the pillar metal 38 as shown in the cross section of FIG. 4.

The cross sections that are shown in FIGS. 3 and 4 and that have been extracted from the above referenced related application have been shown in order to highlight that the referenced application provides of method of creating:
a fine-pitch solder bump
smaller solder bumps
a fine-pitch solder bump of high reliability due to the increased height of the solder bump
a cost-effective solder bump by using standard solder material and eliminating the need for expensive “low-α solder”
a solder bump that allows easy cleaning of flux after the process of flip chip assembly and before the process of underfill and encapsulation
a solder bump which allows easy application of underfill.

Referring now to the cross section that is shown in FIG. 5, there is shown a cross section of the BGA package of the invention whereby the semiconductor device has been encapsulated in a molding compound. The elements that are highlighted in the cross section of FIG. 5 are the following:
50, a semiconductor device that is mounted in the package of the invention shown in cross section in FIG. 5
52, the (BGA) substrate on the surface of which device 50 is mounted
54, the pillar metal of the interface between the device 50 and the BGA substrate 52, similar to pillar metal 38 of FIGS. 3 and 4
56, the solder bump of the interface between the device 50 and the BGA substrate 52, similar to solder bump 42 of FIGS. 3 and 4
58, the contact balls that are used to interconnect the package of the invention with surrounding circuitry
60, molding compound into which the device 50 is embedded for protection against the environment.

The columns 54 of pillar metal typically have a height of between about 10 and 100 μm and more preferably about 50 μm.

The cross section that is shown in FIG. 6 is identical to the cross section of FIG. 5 with the exception of the underfill 62 which is used in stead of the molding compound 60 of FIG. 5.

To further relate the above referenced related application with the present invention, the following comment applies: the creation of the pillar metal 54 and the solder bump 56 starts using the I/O contact pads of device 50 (not shown in FIGS. 5, 6) as the contact pads; that is the I/O contact pads of device 50 take the place of the contact pad 32 of FIGS. 3 and 4 in the creation of the pillar metal 54 and the solder bump 56. The process of creating the pillar metal 54 and the solder bump 56 therefore is as follows:
a layer of dielectric is deposited over the active surface of device 50; the active surface of device 50 is the surface in which I/O contact points have been provided; this surface will face the BGA substrate 52 after mounting of the device 50 on BGA substrate 52
openings are created in the layer of dielectric, exposing the I/O contact pads of device 50; this brings the process of the invention to the point of the related application where contact pads 32 (FIGS. 3, 4) have been created on the surface of the layer 30 of dielectric
a layer of passivation is deposited over the surface of the layer of dielectric, similar to layer 34, FIGS. 3, 4
openings are created in the layer of passivation, partially exposing the surface of the device I/O contact pads
a barrier layer is deposited over the surface of the layer of passivation, identical to layer 36, FIGS. 3, 4
the pillar metal 54 of the solder bump is formed, identical to layer 38, FIGS. 3, 4
the layer of under bump (not shown in FIGS. 5, 6) is created overlying the pillar metal, identical to layer 40, FIGS. 3, 4
the solder bump 56 is formed, identical to layer 42, FIGS. 3, 4
the layer of barrier metal is isotropically (FIG. 3) or anisotropically (FIG. 4) etched.

These above highlighted steps of creating the pillar metal and the solder bump are provided by the referenced related application using the processing steps that have been detailed above and that are in accordance with the referenced related application. Details of these processing steps will therefore not be further highlighted as part of the present application.

Referring now to FIG. 7, there is shown a top view of an array type arrangement of I/O contact points 66 that form the contact points of device 50. This top view of the array type contact points 66 is shown as one example of where the process of creating pillar metal and solder bumps can be applied.

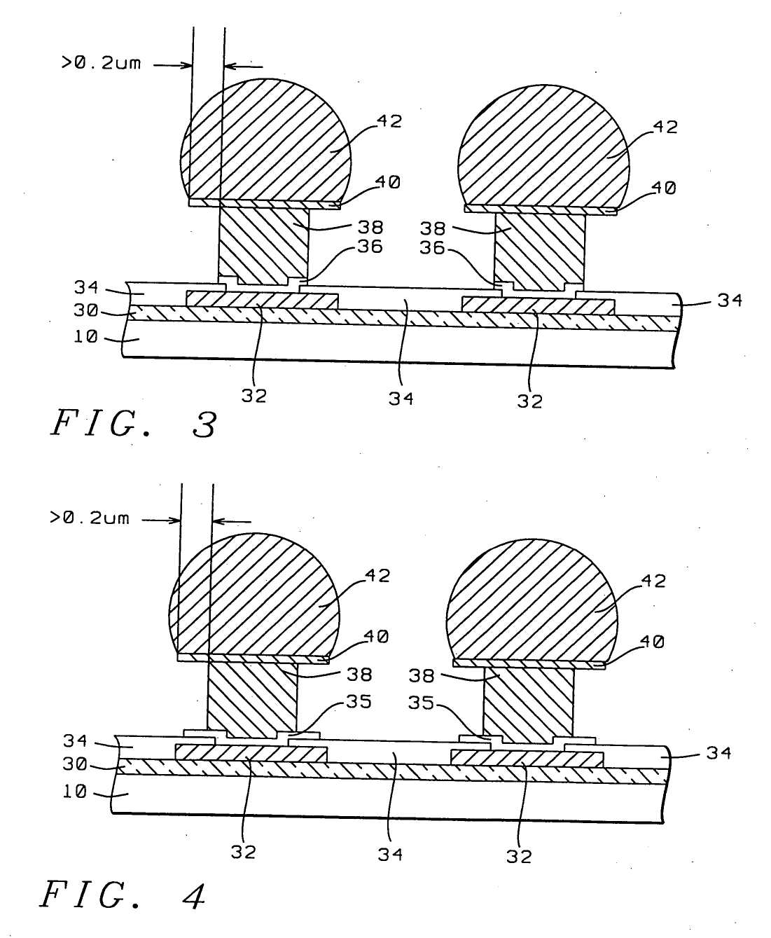

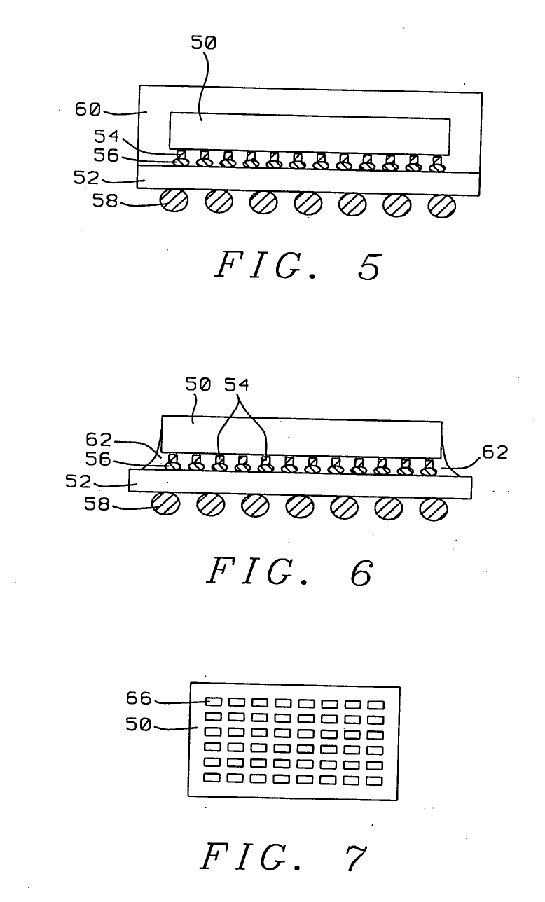

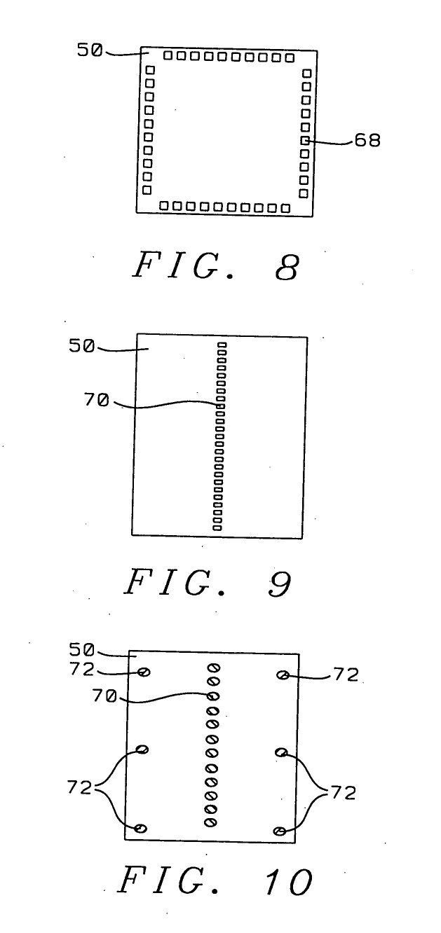

FIGS. 8 and 9 show two more examples of arrangements of I/O contact pads, that are provided on the surface of device 50, where the process of the invention can be applied. FIG. 8 shows a peripheral I/O pad design 68 while FIG. 9 shows a center type pad design 70.

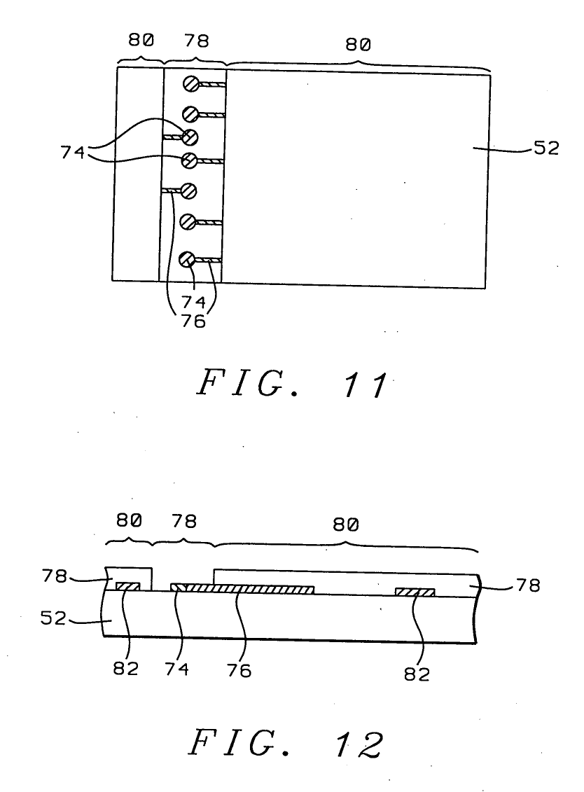

While the peripheral I/O pad design that is shown in FIG. 8 provides evenly distributed mechanical support for device 50, this is not the case for the center pad design that is shown in FIG. 9. For this kind of design, additional mechanical support can be provided to device 50, this is shown in top view in FIG. 10. The elements highlighted as 70 in FIG. 10 are the solder bumps that have been created on the I/O contact pads of device 50, elements 72 are dummy solder bumps that can be provided in order to lend mechanical support to device 50. The symmetry of the dummy bumps 72 as shown in FIG. 10 makes clear that device 50 is, with the dummy bumps 72, adequately and symmetrically supported.

In mounting semiconductor devices on the surface of a BGA substrate, it is important from a manufacturing point of view that solder flux, after the process of solder flow has been completed, can be readily removed. This requires easy access to the surface areas of the BGA substrate where solder flux has been able to accumulate. In addition, the device interconnects (consisting of pillar metal and solder bumps) must, after the pillar metal and the solder bumps have been formed in accordance with the related application, be readily available so that device encapsulants can be adequately applied. More importantly, after flip-chip assembly and solder reflow, the flux that has accumulated in the gap between the semiconductor die and the substrate must be cleaned. For these reasons, it is of value to apply the solder mask not across the entire surface of the substrate (blank deposition) but to leave open the surface areas of the substrate that are immediately adjacent to the I/O interconnects (of pillar metal and solder bumps). This design will create a channel though which the cleaning solution can flow easily. This is highlighted in the top view of FIGS. 11 and 12, where is shown:
52, the BGA substrate on the surface of which device 50 (not shown) is mounted
74, I/O contact pads provided on the surface of substrate 52
76, interconnect traces provided on the surface of substrate 52, connected with contact pads 74
78, the surface region of the substrate 52 over which no solder mask is applied
80, the surface region of the substrate 52 over which a solder mask is applied.

This is further highlighted in the cross section of substrate 52 that is shown in FIG. 12. It is clear that over the region 78, which is the region where no solder mask is applied, the metal pads 74 are readily available so that removal of solder flux and the dispensing of encapsulants can be performed. It must be remembered that this is possible due to the height of the combined pillar metal 54 and the solder bump 56, which results in adequate spacing between the device 50 and the surface of substrate 52. Further shown in FIG. 12 are routing traces 82 that are provided on the surface of substrate 52 for additional interconnect.

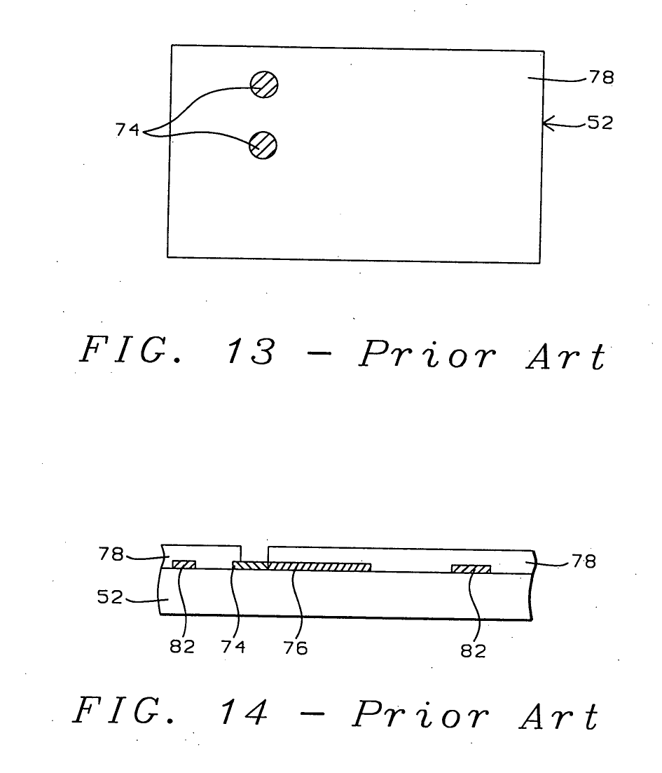

FIGS. 13 and 14 show how prior art procedures and conventions are applied to affect flux removal and encapsulant application. In the prior art application, the metal pads 74 are typically surrounded by the solder mask 78, even for small pitch I/O pad designs. Typically, the solder mask is determined by the type of contact pad design (FIGS. 7 through 9), whereby the contact pads 74 require about 60 μm clearance for reasons of proper alignment registration. This results in the substrate design rule being more critical, allowing for less error and smaller tolerance in the design parameters. In addition, the height of the solder mask 78 is generally about 10 μm larger than the height of the contact pad 74, further forming an obstacle in applying molding compound or in removing flux after the solder process has been completed. These aspects of the prior art are shown in FIGS. 13 and 14, where the metal pads 74 are completely surrounded by the solder mask 78. The present invention negates the highlighted negative effects of the solder mask on flux cleaning and on dispensing molding compound.

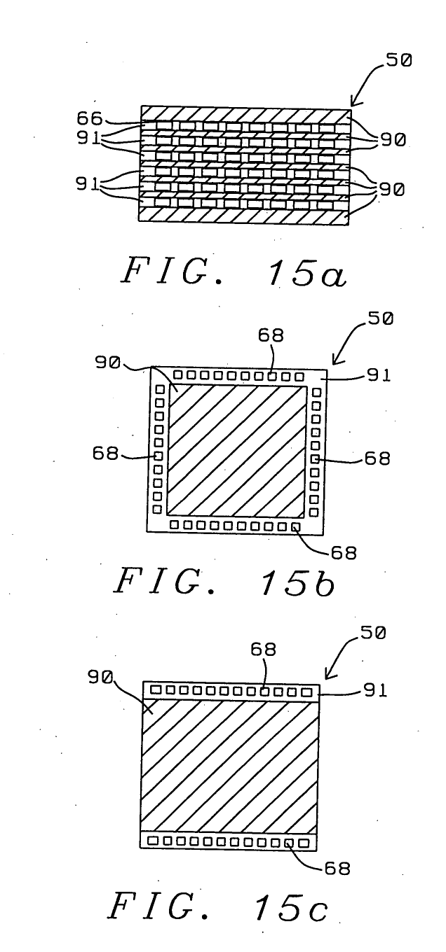

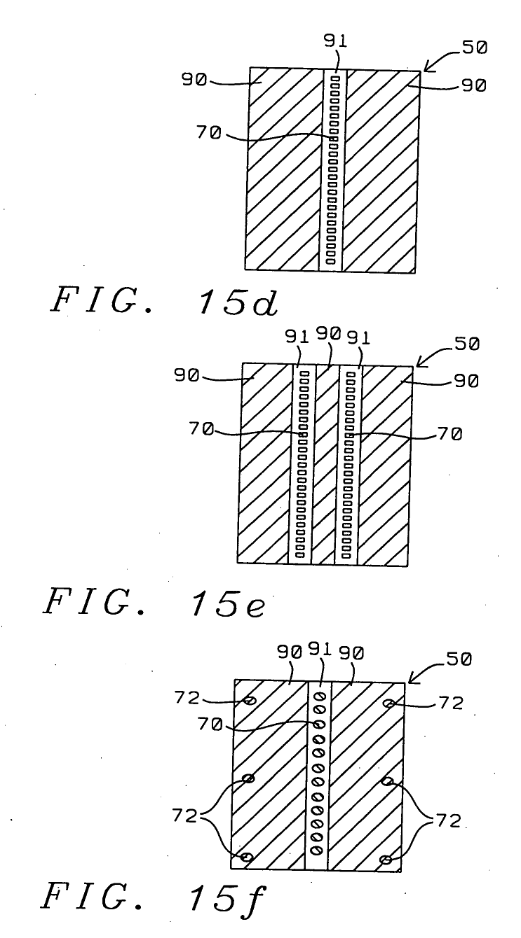

FIGS. 15a through 15f show examples of applications of the invention, as follows:

FIG. 15a shows the application of a solder mask over the surface that has previously been shown in FIG. 7, the solder mask has been indicated with cross-hatched regions 90, the regions where no solder mask is present have been highlighted with 91.

FIGS. 15b and 15c relate to the previous FIG. 8, the solder mask has been highlighted as regions 90 while the regions where no solder mask is present have been highlighted with 91. The design that is shown in FIG. 15c is considered a “partial” peripheral type I/O pad configuration of a semiconductor device since I/O pads 68 are only provided along two opposing sides of the semiconductor device 50.

It must be noted that the designs that are shown in FIGS. 15b and 15c can further be provided with supporting dummy solder bumps in the regions of the solder mask 90, these supporting solder bumps have not been shown in FIGS. 15b and 15c.

FIG. 15d shows the design that has previously been shown in FIG. 9, FIG. 15e shows a design that is similar to the design of FIG. 15d with the exception that the contact points 70 have now been provided in two columns. It is clear from these two drawings that channels have been created in the solder mask that are in line with and include the contact pads. These channels allow for easy flow of cleaning fluid and therefore allow for easy removal of solder flux after the process of chip encapsulation and solder flow has been completed.

FIG. 15f relates to the previously shown FIG. 10, the above observation relating to the creation of a channel through the solder flux and the therefrom following easy flow of cleaning fluid equally applies to the design that is shown in FIG. 15f.

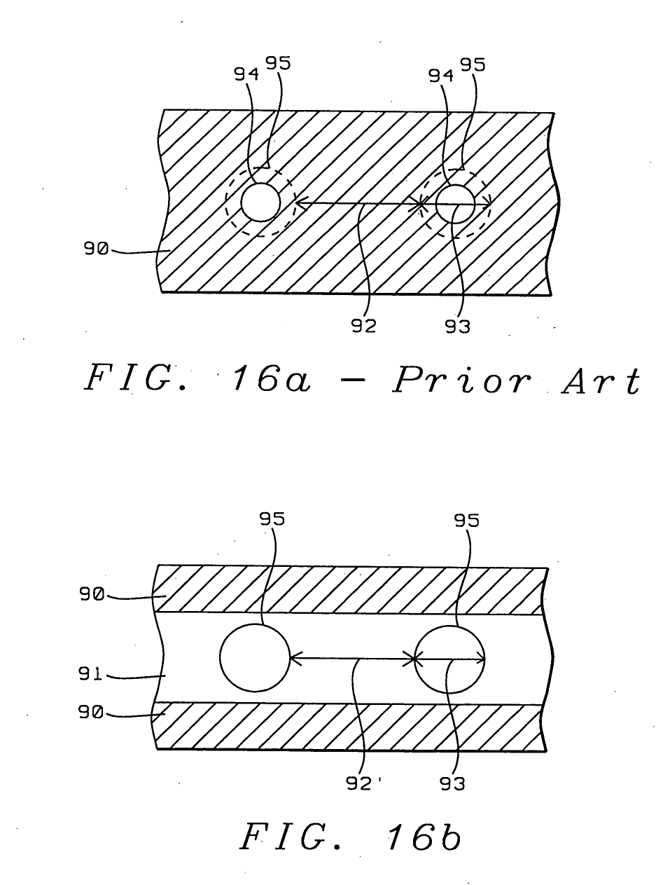

FIGS. 16a and 16b demonstrate how the invention leads to the ability to reduce the pitch between I/O pads.

FIG. 16a shows how in prior art applications the solder mask 90 is provided, further shown in FIG. 16a are:
94, the circumference of the opening that is created in the solder mask 90
95, the circumference of the bond pad on the surface of a semiconductor device
92, the distance (or spacing) S between two adjacent contact pads
93, the diameter D of a contact pad.

In prior art applications as shown in FIG. 16a, the pitch between adjacent contact pads is P=D+S+2×(the required clearance between adjacent contact pads). The required clearance is needed by the solder mask and requires that extra space is required between the circumference 95 of the contact pad and the circumference 94 of the opening created in the solder mask.

With the wide channel created by the invention through the solder mask, highlighted as channel 91 in FIG. 16b, the conventional clearance is not required, resulting in the ability to reduce the pitch between adjacent contact pads 95. This leads to a distance 92′, FIG. 16b, which is smaller than distance 92 of FIG. 16a.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A chip package comprising:
a semiconductor device;
a substrate having a pad having an edge not covered by a mask; and
a bump between said semiconductor device and said substrate, wherein said bump is bonded to said pad.

2. The chip package of claim 1 further comprising a post between said bump and said semiconductor device, wherein said post has a thickness of greater than 10 microns.

3. The chip package of claim 2, wherein said thickness is less than 100 microns.

4. The chip package of claim 2 further comprising a barrier layer between said post and said semiconductor device.

5. The chip package of claim 2 further comprising a metal layer between said post and said bump, wherein said metal layer has a surface on said post, said surface having a region not covered by said post.

6. The chip package of claim 5, wherein the distance between an edge of said metal layer and an edge of said post is greater than 0.2 microns.

7. The chip package of claim 1, wherein said bump comprises solder.

8. The chip package of claim 1, wherein said semiconductor device comprises a pad and a passivation layer, said post over said pad being exposed by an opening in said passivation layer, and wherein said bump is over said pad.

9. The chip package of claim 1 further comprising a barrier between said bump and said pad.

10. The chip package of claim 1, wherein said mask comprises a solder mask.
